(19) United States
(12) Patent Application Publication
(10) Pub. No.: US 2026/0173507 A1
(43) Pub. Date: Jun. 18, 2026

(54) MULTI-REGION SEMICONDUCTOR DEVICE INCLUDING REGIONS WITH DIFFERENT NUMBERS OF GATE CHANNEL LAYERS

(71) Applicant: SAMSUNG ELECTRONICS CO., LTD., Suwon-si (KR)

(72) Inventors: Soohee SHIN, Suwon-si (KR); Heonjong Shin, Suwon-si (KR); Seowoo Nam, Suwon-si (KR); June Young Park, Suwon-si (KR)

(73) Assignee: SAMSUNG ELECTRONICS CO., LTD., Suwon-si (KR)

(21) Appl. No.: 19/240,865

(22) Filed: Jun. 17, 2025

(30) Foreign Application Priority Data
Dec. 13, 2024 (KR) 10-2024-0186372

(51) Int. Cl. H10D 84/83; H01L 23/528; H10D 30/00; H10D 30/01; H10D 30/43; H10D 62/10; H10D 62/13; H10D 64/23; H10D 84/01

(52) U.S. Cl. CPC H10D 84/8312; H10D 30/43; H10D 30/502; H10D 62/121; H10D 62/151; H10D 64/254; H10D 64/256; H10D 84/8311; H10D 84/83138; H10D 84/832; H10W 20/435; H10D 30/014; H10D 30/0191; H10D 84/0149

(57) ABSTRACT

A semiconductor device including: a first region including: first sheet patterns vertically stacked; first gate patterns alternately stacked with the first sheet patterns; first and second source/drain patterns on either side of the first sheet patterns; a dummy contact connected to the first source/drain pattern; and a first upper wiring structure vertically spaced apart from the dummy contact; and a second region including: second sheet patterns vertically stacked; second gate patterns alternately stacked with the second sheet patterns; and third and fourth source/drain patterns on either side of the second sheet patterns; wherein the layers of the first gate patterns are less than the layers of the second gate patterns, wherein a vertical level of a lowermost first gate pattern is higher than a vertical level of a lowermost second gate pattern, and wherein the dummy contact is insulated from a wiring line in the first upper wiring structure.

### CROSS-REFERENCE TO RELATED APPLICATION

This application is based on and claims priority to Korean Patent Application No. 10-2024-0186372, filed in the Korean Intellectual Property Office on Dec. 13, 2024, the entire contents of which are hereby incorporated by reference.

### BACKGROUND

### 1. Field

The present disclosure relates to a semiconductor device.

### 2. Description of Related Art

Semiconductor devices can be used as components for storing data or controlling electrical signals in electronic devices, and various types of semiconductor devices can be manufactured for this purpose. For example, a memory device may be mainly used to store and retrieve data, while a non-memory device may be used to control or amplify an electrical signal. Semiconductor devices are a core component of an electronic device and are used in various fields including computers, communication equipment, consumer electronics, etc.

With the development of industry, the performance and function requirements for the electronic devices are increasingly growing. Accordingly, high-performance characteristics in semiconductor devices are essentially required, and the integration density of the semiconductor devices is increasing to meet these requirements. Various methods for forming semiconductor devices having excellent performance and improved integration density are being studied.

### SUMMARY

Provided is a semiconductor device with improved reliability and integration density.

According to an aspect of the disclosure, a semiconductor device includes: a first device region including: a plurality of first sheet patterns stacked in a vertical direction; a plurality of first gate patterns alternately stacked with the plurality of first sheet patterns; a first source/drain pattern on one side of the plurality of first sheet patterns; a second source/drain pattern on another side of the plurality of first sheet patterns; an upper dummy contact connected to an upper surface of the first source/drain pattern; and a first upper wiring structure spaced apart from the upper dummy contact in the vertical direction; and a second device region including: a plurality of second sheet patterns stacked in the vertical direction; a plurality of second gate patterns alternately stacked with the plurality of second sheet patterns; a third source/drain pattern on one side of the plurality of second sheet patterns; and a fourth source/drain pattern on the other side of the plurality of second sheet patterns, wherein a number of layers of the plurality of first gate patterns is less than a number of layers of the plurality of second gate patterns, wherein a vertical level of a lowermost first gate pattern among the plurality of first gate patterns is higher than a vertical level of a lowermost second gate pattern among the plurality of second gate patterns, and wherein the upper dummy contact is insulated from a wiring line included in the first upper wiring structure.

According to an aspect of the disclosure, a semiconductor device includes: a first device region including: a plurality of first sheet patterns stacked in a vertical direction; a plurality of first gate patterns alternately stacked with the plurality of first sheet patterns; a first source/drain pattern on one side of the plurality of first sheet patterns; a second source/drain pattern on the other side of the plurality of first sheet patterns, an upper dummy contact connected to an upper surface of the first source/drain pattern; a first lower contact connected to a lower surface of the first source/drain pattern; a first lower wiring line connected to the first lower contact; a first upper contact connected to an upper surface of the second source/drain pattern; and a first upper wiring structure connected to the first upper contact, the first upper wiring structure including a first upper wiring line; and a second device region including: a plurality of second sheet patterns stacked in the vertical direction; a plurality of second gate patterns alternately stacked with the plurality of second sheet patterns; a third source/drain pattern on one side of the plurality of second sheet patterns; a fourth source/drain pattern on another side of the plurality of second sheet patterns; a second lower contact connected to a lower surface of the third source/drain pattern; and a second lower wiring line connected to the second lower contact, wherein a number of layers of the plurality of first gate patterns is less than a number of layers of the plurality of second gate patterns, wherein a distance between an upper surface of the first lower wiring line and a lower surface of a lowermost first gate pattern among the plurality of first gate patterns is greater than a distance between an upper surface of the second lower wiring line and a lower surface of a lowermost second gate pattern among the plurality of second gate patterns, and wherein the upper dummy contact is insulated from a wiring line included in the first upper wiring structure.

According to an aspect of the disclosure, a semiconductor device includes: a first device region including: a plurality of first sheet patterns stacked in a vertical direction; a plurality of first gate patterns alternately stacked with the plurality of first sheet patterns; a first source/drain pattern on one side of the plurality of first sheet patterns; a second source/drain pattern disposed on another side of the plurality of first sheet patterns; an upper dummy contact connected to an upper surface of the first source/drain pattern; a first lower contact connected to a lower surface of the first source/drain pattern; a first lower wiring line connected to the first lower contact; a first upper contact connected to an upper surface of the second source/drain pattern; and a first upper wiring structure connected to the first upper contact, the first upper wiring structure including a first upper wiring line; and a second device region including: a plurality of second sheet patterns stacked in the vertical direction; a plurality of second gate patterns alternately stacked with the plurality of second sheet patterns; a third source/drain pattern on one side of the plurality of second sheet patterns; a fourth source/drain pattern on another side of the plurality of second sheet patterns; a second lower contact connected to a lower surface of the third source/drain pattern; a second lower wiring line connected to the second lower contact; a second upper contact connected to an upper surface of the fourth source/drain pattern; and a second upper wiring structure including a second upper wiring line connected to the second upper contact, wherein a number of layers of the plurality of first gate patterns is less than a number of layers of the plurality of second gate patterns, wherein a distance between an upper surface of the first lower wiring line and a lower surface of a lowermost first gate pattern among the plurality of first gate patterns is greater than a distance between an upper surface of the second lower wiring line and a lower surface of a lowermost second gate pattern among the plurality of second gate patterns, and wherein the upper dummy contact is insulated from a wiring line included in the first upper wiring structure.

According to an aspect of the disclosure, a method of manufacturing a semiconductor device includes: forming a lower pattern on a substrate in each of a first device region and a second device region; in each of the first device region and the second device region, alternately stacking sheet patterns and sacrificial semiconductor layers on the lower pattern; forming, in the first device region, a first source/drain region and a second source/drain region on the lower pattern; removing the sacrificial semiconductor layers; sequentially forming, in the first device region, a first gate insulating film and a first gate pattern on the sheet patterns; forming, in the second device regions, a third source/drain pattern and a fourth source/drain pattern on the lower pattern; forming, in the first device region, an upper dummy contact on the first source/drain pattern, and a first upper contact on the second source/drain pattern; forming, in the second device region, a second upper contact on the fourth source/drain pattern; forming, in the first device region, a first upper insulating layer on the first gate capping pattern and a first interlayer insulating film; forming, in the first device region, a first upper via on the first upper contact; forming, in the first device region, a second upper insulating layer on the first upper insulating layer; forming, in the first device region, a first upper wiring line on the first upper via; removing the substrate and the lower pattern; forming a first lower insulating layer in the first device region and a third lower insulating layer in the second device region; forming, in the first device region, a first lower contact in the first lower insulating layer; and forming, in the second device region, a second lower contact in the third lower insulating layer.

According to some aspects of the present disclosure, the electrical characteristics and reliability of the semiconductor device can be improved.

According to some aspects of the present disclosure, a degree of design freedom and a degree of process freedom of the semiconductor device can be improved.

According to some aspects of the present disclosure, in a structure that includes device regions with different numbers of active channel pattern layers, the contact resistance of the semiconductor devices can be reduced by arranging the dummy contacts in the low layer channel pattern region, thereby improving the electrical performance of the semiconductor devices.

The effects that can be obtained through the present disclosure are not limited to those described above. Technical effects not mentioned herein will be clearly understood by those skilled in the art from the description of the present disclosure described below.

### BRIEF DESCRIPTION OF DRAWINGS

The above and other objects and features of the present disclosure will become more apparent from the following description taken in conjunction with the accompanying drawings, in which:

FIG. 1 is an example plan view provided to explain a semiconductor device according to one or more embodiments of the present disclosure;

FIG. 2 is a cross-sectional view taken along line A-A of FIG. 1;

FIG. 3 is a cross-sectional view taken along line B-B of FIG. 1;

FIG. 4 is a diagram provided to explain a semiconductor device according to one or more embodiments of the present disclosure;

FIG. 5 is a diagram provided to explain a semiconductor device according to one or more embodiments of the present disclosure;

FIG. 6 is a diagram provided to explain a semiconductor device according to one or more embodiments of the present disclosure;

FIG. 7 is a diagram provided to explain a semiconductor device according to one or more embodiments of the present disclosure;

FIG. 8 is a diagram provided to explain a semiconductor device according to one or more embodiments of the present disclosure;

FIG. 9 is a diagram provided to explain a semiconductor device according to one or more embodiments of the present disclosure;

FIGS. 10 to 16 are diagrams showing intermediate stages, which are provided to explain a method for manufacturing a semiconductor device according to one or more embodiments of the present disclosure; and

FIGS. 17 to 19 are diagrams showing intermediate stages, which are provided to explain a method for manufacturing a semiconductor device according to one or more embodiments of the present disclosure.

### DETAILED DESCRIPTION

Hereinafter, various aspects of the present disclosure will be described with reference to the drawings. Throughout the description, the same reference numerals may refer to the same components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

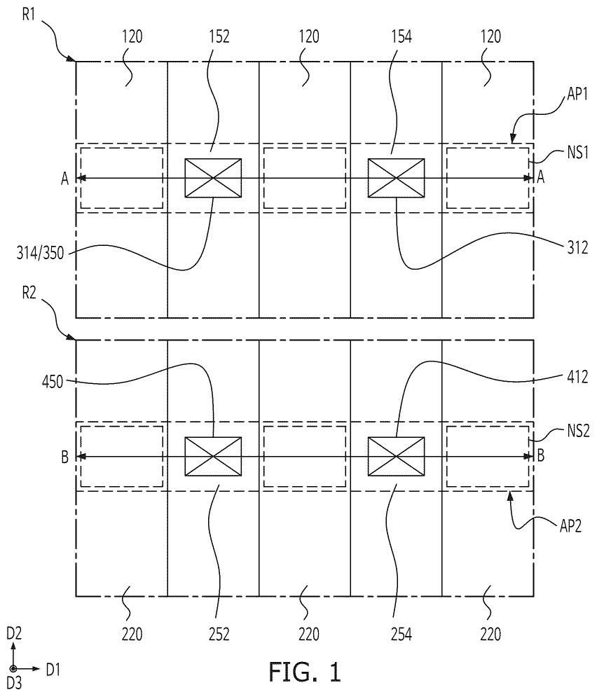

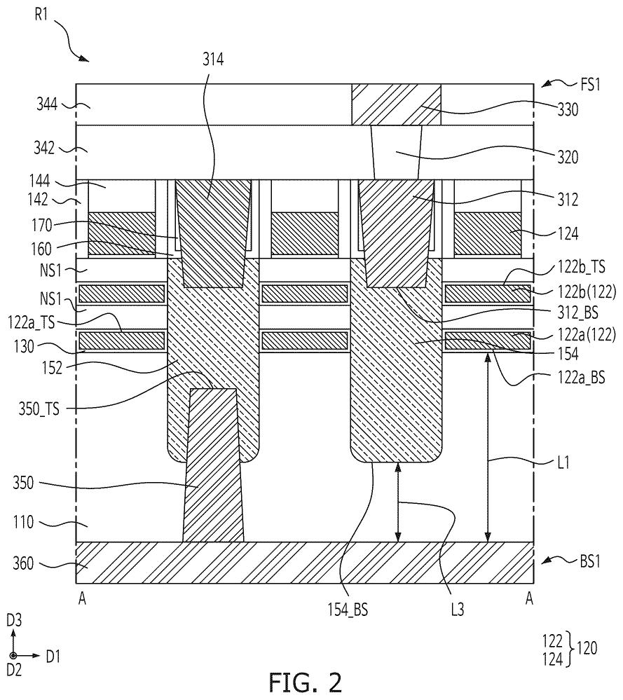

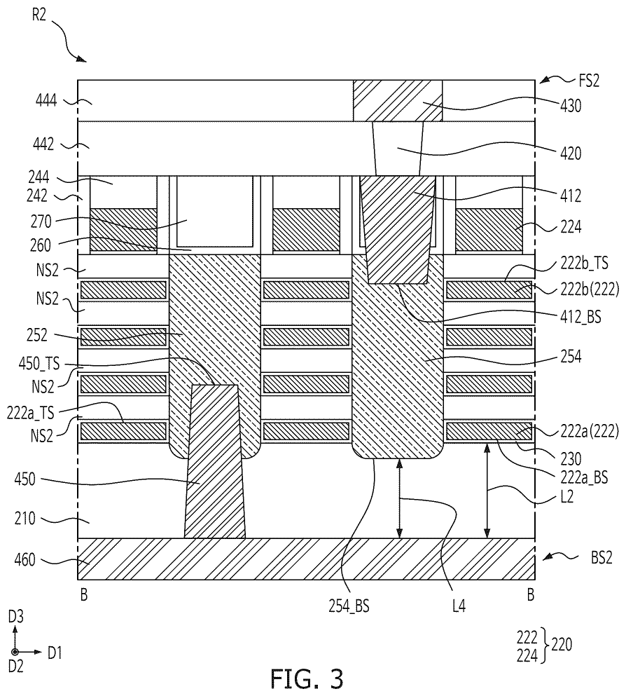

FIG. 1 is an example plan view provided to explain a semiconductor device. FIG. 2 is a cross-sectional view taken along line A-A of FIG. 1. FIG. 3 is a cross-sectional view taken along line B-B of FIG. 1.

Referring to FIGS. 1 to 3, the semiconductor device may include a MOSFET, and more specifically, may include a semiconductor device referred to as a gate-all-around (GAA) transistor and a multi-bridge channel FET (MBCFET). However, the disclosure is not limited thereto. For example, a semiconductor device may include a fin-type transistor (FinFET) including a fin-type pattern-shaped channel region.

The semiconductor device may include a first device region R1 and a second device region R2. The first device region R1 and the second device region R2 may be disposed within a single semiconductor chip. In one or more embodiments, the first device region R1 and the second device region R2 may each be disposed on a plurality of semiconductor chips.

The first device region R1 and the second device region R2 may be disposed within a single semiconductor shot region that is simultaneously exposed during a photolithography process. Alternatively, the first device region R1 and the second device region R2 may be different regions from each other in a single nanosheet stacked structure. However, the disclosure is not limited thereto.

The first device region R1 may include a low layer channel pattern, and the second device region R2 may include a high layer channel pattern. For example, the number of active sheet patterns in the first device region R1 may be less than the number of active sheet patterns in the second device region R2. In addition, the number of gate pattern layers in the first device region R1 may be less than the number of gate pattern layers in the second device region R2.

Hereinafter, the first device region R1 will be described.

The first device region R1 may include a first lower insulating layer 110, a plurality of first sheet patterns NS1, a plurality of first gate patterns 120, a first source/drain pattern 152, a second source/drain pattern 154, a first etching stop film 160, a first interlayer insulating film 170, a first upper contact 312, an upper dummy contact 314, a first upper via 320, a first upper insulating layer 342, a first upper wiring structure FS1, a first lower contact 350, and a first lower wiring structure BS1.

The first lower insulating layer 110 may include at least one of, for example, silicon oxide, silicon nitride, silicon oxynitride, or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or any combination of these. However, the disclosure is not limited thereto.

The first device region R1 may include a first active region AP1. The first active region AP1 may be disposed on the first lower insulating layer 110. The first active region AP1 may extend in a first direction D1. The first direction D1 may be a direction intersecting with a second direction D2. Each of the first and second directions D1 and D2 may be a direction parallel to an upper surface or a lower surface of a first lower wiring line 360.

A channel pattern and the first and second source/drain patterns 152 and 154 may be disposed in the first active region AP1. The channel pattern may represent a sheet pattern from the plurality of first sheet patterns NS1 which is surrounded by the gate patterns on its upper surface, a lower surface, and both side surfaces.

The plurality of first sheet patterns NS1 may be disposed on the first lower insulating layer 110. The plurality of first sheet patterns NS1 may be stacked in a vertical direction (e.g., a third direction D3). The third direction D3 may be a direction intersecting with each of the first and second directions D1 and D2. The third direction D3 may be a direction perpendicular to the upper surface or the lower surface of the first lower wiring line 360. The plurality of first sheet patterns NS1 may be nanowire patterns, but are not limited thereto.

The first sheet pattern NS1 may include one of an elemental semiconductor material such as silicon (Si), silicon germanium (SiGe), a group IV-IV compound semiconductor, or a group III-V compound semiconductor. For example, the group IV-IV compound semiconductor may be a binary compound or a ternary compound including at least two or more of carbon (C), silicon (Si), germanium (Ge), and tin (Sn). For example, the group III-V compound semiconductor may be one of a binary compound, a ternary compound, or a quaternary compound formed by a combination of at least one of aluminum (Al) or gallium (Ga), and indium (In) as a group III element and one of phosphorus (P), arsenic (As), and antimony (Sb) as a group V element.

A field insulating film may be disposed between first active regions AP1 adjacent to each other in the second direction D2. The field insulating film may be disposed between adjacent first lower insulating layers 110. The field insulating film may extend in the first direction D1. For example, the field insulating film may include oxide, nitride, nitride oxide, or a combination thereof. The field insulating film may include a plurality of films.

The plurality of first gate patterns 120 may be disposed on the first lower insulating layer 110. The plurality of first gate patterns 120 may be alternately stacked with the plurality of first sheet patterns NS1. The plurality of first gate patterns 120 may be pattern layers of gate electrodes appearing on a cross-section (e.g., an A-A cross-section) of the semiconductor device. In addition, the plurality of first gate patterns 120 may refer to the gate electrodes surrounding the plurality of first sheet patterns NS1. The plurality of first gate patterns 120 may surround the upper surface, the lower surface, and both side surfaces of each of the plurality of first sheet patterns NS1, and may extend in the second direction D2. The upper and lower surfaces of the first sheet pattern NS1 may refer to the surfaces that intersect with the third direction D3, and the expression “both side surfaces” of the first sheet pattern NS1 may refer to the surfaces that intersect with the second direction D2.

The plurality of first gate patterns 120 may include first lower gate patterns 122 and a first upper gate pattern 124. The first lower gate patterns 122 may be disposed between the first sheet patterns NS1 adjacent to each other in the third direction D3. The first lower gate patterns 122 may be disposed between the plurality of first sheet patterns NS1, and may be disposed between the first lower insulating layer 110 and the lowermost first sheet pattern NS1 among the plurality of first sheet patterns NS1. The first upper gate pattern 124 may be disposed on the plurality of first sheet patterns NS1. For example, the first upper gate pattern 124 may be disposed on the uppermost first sheet pattern NS1 among the plurality of first sheet patterns NS1. The first upper gate pattern 124 may include a plurality of layers. For example, the first upper gate pattern 124 may include a plurality of layers including a work function adjustment film.

The first gate pattern 120 may include at least one of a metal, a metal alloy, a conductive metal nitride, a metal silicide, a doped semiconductor material, a conductive metal oxide, or a conductive metal oxynitride. For example, the first gate pattern 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and any combination of these, but the disclosure is not limited thereto. The conductive metal oxide and the conductive metal oxynitride may include a form in which the material mentioned above is oxidized, but the disclosure is not limited thereto.

A first gate insulating film 130 may be disposed between the first gate pattern 120 and the first sheet pattern NS1, between the first gate pattern 120 and the first lower insulating layer 110, between the first gate pattern 120 and the first source/drain pattern 152, and between the first gate pattern 120 and the second source/drain pattern 154. Specifically, the first gate insulating film 130 may be disposed between the first upper gate pattern 124 and the uppermost first sheet pattern among the plurality of first sheet patterns NS1. The first gate insulating film 130 may be disposed between the first lower gate pattern 122 and the first sheet pattern NS1. The first gate insulating film 130 may surround the upper surface, the lower surface, and both side surfaces of each of the plurality of first sheet patterns NS1. The first gate insulating film 130 may extend in the first direction D1 along the upper and lower surfaces of the first sheet pattern NS1.

The first gate insulating film 130 may include a plurality of films. For example, the first gate insulating film 130 may include an interfacial insulating film and a high-k insulating film. For example, the interfacial insulating film may include silicon oxide. The high-k insulating film may include a high-k material having a dielectric constant greater than that of the interfacial insulating film. For example, the high-k insulating film may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A first gate spacer 142 may be disposed on a side surface of the first upper gate pattern 124. For example, the first gate spacer 142 may extend in the second direction D2 along the side surface of the first upper gate pattern 124. The first gate spacer may not be positioned between the first lower insulating layer 110 and the first sheet pattern NS1. In addition, the first gate spacer may not be positioned between the first sheet patterns NS1 adjacent to each other in the third direction D3.

For example, the first gate spacer 142 may include at least one of silicon nitride (SiN), silicon nitride oxide (SiON), silicon oxide (SiO₂), silicon carbonate nitride (SiOCN), silicon boron nitride (SiBN), silicon oxide boron nitride (SiOBN), silicon oxide carbonate (SiOC), or any combination of these. Although it is illustrated that the first gate spacer 142 is a single film, it is only for convenience of description, and the disclosure is not limited thereto.

A first gate capping pattern 144 may be disposed on an upper surface of the first upper gate pattern 124. The first gate capping pattern 144 may cover the upper surface of the first upper gate pattern 124. The first gate capping pattern 144 may overlap with the first upper gate pattern 124 in the third direction D3. A side surface of the first gate capping pattern 144 may be in contact with the first gate spacer 142. The first gate capping pattern 144 may be disposed on the upper surfaces of the first upper gate pattern 124 and the first gate spacer 142. An upper surface of the first gate capping pattern 144 may be disposed on the same plane as an upper surface of the first interlayer insulating film 170, but the disclosure is not limited thereto. The side surface of the first gate capping pattern 144 may be in contact with the first etching stop film 160.

For example, the first gate capping pattern 144 may include at least one of silicon nitride (SiN), silicon oxynitride (SiON), silicon carbonitride (SiCN), silicon oxycarbonitride (SiOCN), or any combination of these. The first gate capping pattern 144 may include a material having etch selectivity with respect to the first interlayer insulating film 170.

The first and second source/drain patterns 152 and 154 may be disposed in the first active region AP1. The first and second source/drain patterns 152 and 154 may be disposed on the first lower insulating layer 110. Each of the first and second source/drain patterns 152 and 154 may be disposed on both sides of the plurality of first gate patterns 120. For example, the first source/drain pattern 152 may be disposed on one side of the plurality of first gate patterns 120. In addition, the second source/drain pattern 154 may be disposed on the other side of the plurality of first gate patterns 120. Portions of the side surfaces of the first and second source/drain patterns 152 and 154 may be in direct contact with the first gate insulating film 130.

The first and second source/drain patterns 152 and 154 may be disposed on both sides of the plurality of first sheet patterns NS1. For example, the first source/drain pattern 152 may be disposed on one side (e.g., one side surface) of the plurality of first sheet patterns NS1. In addition, the second source/drain pattern 154 may be disposed on the other side (e.g., the other side surface) of the plurality of first sheet patterns NS1. Portions of the side surfaces of the first and second source/drain patterns 152 and 154 may be in direct contact with the plurality of first sheet patterns NS1.

The first source/drain pattern 152 may be disposed to be spaced apart from the second source/drain pattern 154. For example, the first source/drain pattern 152 may be disposed to be spaced apart from the second source/drain pattern 154 in the first direction D1. However, the disclosure is not limited thereto. For example, the first source/drain pattern 152 and the second source/drain pattern 154 may be disposed to be spaced apart from each other in the second direction D2. That is, the first and second source/drain patterns 152 and 154 and the second source/drain pattern 154 may be disposed in different first active regions AP1.

Each of the first and second source/drain patterns 152 and 154 may be an epitaxial pattern formed by a selective epitaxial growth process that uses the first sheet pattern NS1 as a seed. Each of the first and second source/drain patterns 152 and 154 may serve as a source/drain of a transistor that uses the first sheet pattern NS1 as a channel region.

Each of the first and second source/drain patterns 152 and 154 may include a semiconductor material. Each of the first and second source/drain patterns 152 and 154 may include, for example, an elemental semiconductor material such as silicon (Si) or germanium (Ge). In addition, each of the first and second source/drain patterns 152 and 154 may include, for example, a binary compound, a ternary compound including at least two or more of carbon (C), silicon (Si), germanium (Ge), or tin (Sn), or a compound of these doped with a group IV element. For example, each of the first and second source/drain pattern 152 and 154 may include silicon (Si), silicon-germanium (SiGe), germanium (Ge), silicon carbide (SiC), etc., but is not limited thereto.

Each of the first and second source/drain patterns 152 and 154 may include a dopant doped into a semiconductor material. The doped dopant may include at least one of boron (B), aluminum (Al), gallium (Ga), indium (In), phosphorus (P), carbon (C), arsenic (As), antimony (Sb), bismuth (Bi), or oxygen (O), but is not limited thereto. Each of the first and second source/drain patterns 152 and 154 may include a plurality of films having different dopant concentrations.

The first active region AP1 may be a region in which a PMOS or an NMOS is formed. For example, the first active region AP1 may be a region in which the PMOS is formed. In this case, each of the first and second source/drain patterns 152 and 154 may include a P-type material. Alternatively, the first active region AP1 may be a region in which the NMOS is formed. In this case, each of the first and second source/drain patterns 152 and 154 may include an N-type material.

The first etching stop film 160 may be disposed on an upper surface of the first source/drain pattern 152 and an upper surface of the second source/drain pattern 154. The first etching stop film 160 may extend along a side surface of the first gate spacer 142. The first etching stop film 160 may include a material that has etching selectivity with respect to the first interlayer insulating film 170. For example, the first etching stop film 160 may include at least one of silicon nitride (SiN), silicon oxide (SiO), silicon oxynitride (SiON), silicon carbonate nitride (SiOCN), silicon boron nitride (SiBN), silicon oxide boron nitride (SiOBN), silicon oxynitride (SiOC), or any combination of these.

The first interlayer insulating film 170 may be disposed on the first etching stop film 160. The first interlayer insulating film 170 may be disposed on the first source/drain pattern 152 and the second source/drain pattern 154. The first interlayer insulating film 170 may be disposed on one side of the first upper gate pattern 124. The first interlayer insulating film 170 may be disposed between the first upper gate patterns 124.

For example, the first interlayer insulating film 170 may include at least one of silicon oxide (SiO), silicon nitride (SiN), silicon oxynitride (SiON), or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or any combination of these, but is not limited thereto.

The first upper contact 312 may be connected to the upper surface of the second source/drain pattern 154. For example, the first upper contact 312 may be formed through the first interlayer insulating film 170 and the first etching stop film 160 and connected to the second source/drain pattern 154. In addition, the first upper contact 312 may be formed through the upper surface of the second source/drain pattern 154 and inside an upper region of the second source/drain pattern 154. The first upper contact 312 may be connected to a first upper wiring line 330 included in the first upper wiring structure FS1. For example, the first upper contact 312 may be connected to the first upper wiring line 330 through the first upper via 320.

The first upper contact 312 may be positioned at a vertical level lower than a vertical level of the uppermost first sheet pattern among the plurality of first sheet patterns NS1. For example, a vertical level of a lower surface 312_BS of the first upper contact 312 may be lower than a vertical level of an upper surface 122b_TS of an uppermost first gate pattern 122b among the first lower gate patterns 122. The vertical level referred to herein may represent a vertical level in the third direction D3. The vertical level may represent a distance from a reference level to a surface of a specific configuration in the third direction D3. The reference level may be a vertical level corresponding to an upper or lower surface of any component (e.g., the lower wiring lines 360 and 460) having a planar surface.

The first upper contact 312 may include a conductive material. For example, the first upper contact 312 may include at least one of ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) and a two-dimensional material (2D material), aluminum (Al), copper (Cu), tungsten (W), cobalt (Co), ruthenium (Ru), silver (Ag), gold (Au), manganese (Mn), or molybdenum (Mo).

The first upper via 320 may be disposed in the first upper insulating layer 342. The first upper via 320 may be formed through the first upper insulating layer 342. The first upper insulating layer 342 may be disposed on an upper surface of the first gate capping pattern 144 and on an upper surface of the first interlayer insulating film 170. The first upper via 320 may be disposed on the first upper contact 312. The first upper via 320 may be connected to the first upper contact 312. An interlayer etching stop film may be disposed between the first upper insulating layer 342 and the first gate capping pattern 144 and between the first upper insulating layer 342 and the first interlayer insulating film 170.

The first upper via 320 may include a conductive material. For example, the first upper via 320 may include at least one of molybdenum (Mo), ruthenium (Ru), cobalt (Co), nickel (Ni), nickel boron (NiB), tungsten (W), tungsten nitride (WN), tungsten oxycarbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional material (2D material), aluminum (Al), copper (Cu), tungsten (W), cobalt (Co), ruthenium (Ru), silver (Ag), gold (Au), or manganese (Mn).

The upper dummy contact 314 may be connected to the upper surface of the first source/drain pattern 152. For example, the upper dummy contact 314 may be formed through the first interlayer insulating film 170 and the first etching stop film 160 and connected to the first source/drain pattern 152. In addition, the upper dummy contact 314 may be formed through the upper surface of the first source/drain pattern 152 and inside an upper region of the first source/drain pattern 152.

The upper dummy contact 314 may include a conductive material. The description of the material of the upper dummy contact 314 may be the same as the description of the material of the first upper contact 312.

The upper dummy contact 314 may be insulated from a wiring line included in the first upper wiring structure FS1. In other words, the upper dummy contact 314 may be positioned to be spaced apart from the wiring line of the first upper wiring structure FS1 in the third direction D3, and may not be connected to the wiring line of the first upper wiring structure FS1 that including the first upper wiring line 330.

The first upper wiring structure FS1 may be disposed on the first upper insulating layer 342. The first upper wiring structure FS1 may include the first upper wiring line 330 and a second upper insulating layer 344.

The first upper wiring line 330 may be disposed in the second upper insulating layer 344. The first upper wiring line 330 may be disposed on the first upper via 320. The first upper wiring line 330 may be connected to the first upper via 320. The first upper wiring line 330 may extend in the second direction D2. However, the disclosure is not limited to the above. For example, the first upper wiring line 330 may extend in the first direction D1.

For example, the first upper wiring line 330 may include at least one of molybdenum (Mo), copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al), zirconium (Zr), tungsten (W), ruthenium (Ru), iridium (Ir), or rhodium (Rh). However, the disclosure is not limited to the above.

The description of the material of the first upper insulating layer 342 and the second upper insulating layer 344 may be the same as the description of the material of the first lower insulating layer 110.

The first lower contact 350 may be connected to a lower surface of the first source/drain pattern 152. For example, the first lower contact 350 may be formed through the first lower insulating layer 110 and connected to the first source/drain pattern 152. In addition, the first lower contact 350 may be formed through the lower surface of the first source/drain pattern 152 and inside a lower region of the first source/drain pattern 152. The first lower contact 350 may be connected to the first lower wiring line 360 included in the first lower wiring structure BS1.

A vertical level of an upper surface 350_TS of the first lower contact 350 may be lower than a vertical level of a lower surface 122a_BS of the lowermost gate pattern among the plurality of first gate patterns 120. The first lower contact 350 may not overlap with the plurality of first gate patterns 120 in the first direction D1. For example, the plurality of first gate patterns 120 may not include the gate patterns overlapping with the first lower contact 350 in the first direction D1.

The first lower contact 350 may include a conductive material. The description of the material of the first lower contact 350 may be the same as the description of the material of the first upper contact 312.

The first lower wiring structure BS1 may be disposed on a lower surface of the first lower insulating layer 110. The first lower wiring structure BS1 may include the first lower wiring line 360 and a second lower insulating layer. The first lower wiring structure BS1 may be a backside power delivery network (BSPDN).

The description of the material of the first lower wiring line 360 may be the same as the description of the material of the first upper wiring line 330.

Hereinafter, the second device region R2 will be described.

The second device region R2 may include a third lower insulating layer 210, a plurality of second sheet patterns NS2, a plurality of second gate patterns 220, a third source/drain pattern 252, a fourth source/drain pattern 254, a second etching stop film 260, a second interlayer insulating film 270, a second upper contact 412, a second upper via 420, a third upper insulating layer 442, a second upper wiring structure FS2, a second lower contact 450, and a second lower wiring structure BS2.

The second device region R2 may be identical to the configuration of the first device region R1 except for a configuration in which the number of active sheet patterns is greater than the number of active sheet patterns in the first device region R1, a configuration in which the number of gate pattern layers is greater than the number of gate pattern layers in the first device region R1, a configuration in which the upper dummy contact 314 is not included, etc. Hereinafter, the configurations of the second device region R2 of FIG. 3 will be described, omitting the description of configurations that overlap with the first device region R1 of FIG. 2.

The second device region R2 may include a second active region AP2. The second active region AP2 may be disposed on the third lower insulating layer 210. The second active region AP2 may extend in the first direction D1. A channel pattern and the third and fourth source/drain patterns 252 and 254 may be disposed in the second active region AP2. The channel pattern may represent a sheet pattern from the plurality of second sheet patterns NS2 which is surrounded by the gate patterns on its upper surface, a lower surface, and both side surfaces.

The description of the third lower insulating layer 210 may correspond to, or similarly be applied to, the description of the first lower insulating layer 110 of the first device region R1.

The number of layers of the plurality of second sheet patterns NS2 may be greater than the number of layers of the plurality of first sheet patterns NS1. In this case, a vertical level of an uppermost second sheet pattern among the plurality of second sheet patterns NS2 may correspond to a vertical level of an uppermost first sheet pattern among the plurality of first sheet patterns NS1. For example, a vertical level of a lowermost second sheet pattern among the plurality of second sheet patterns NS2 may be lower than a vertical level of a lowermost first sheet pattern among the plurality of first sheet patterns NS1. In other words, the number of layers of the plurality of second sheet patterns NS2 may be greater than the number of layers of the plurality of first sheet patterns NS1. In addition to the above description, the description of the plurality of second sheet patterns NS2 may correspond to, or similarly be applied to, the description of the plurality of first sheet patterns NS1 of the first device region R1.

The plurality of second gate patterns 220 may include second lower gate patterns 222 and a second upper gate pattern 224. The second lower gate patterns 222 may be disposed between the second sheet patterns NS2 adjacent to each other in the third direction D3. The second upper gate pattern 224 may be disposed on the plurality of second sheet patterns NS2.

The number of layers of the plurality of second gate patterns 220 may be greater than the number of layers of the plurality of first gate patterns 120. In this case, a vertical level of an upper surface 222b_TS of an uppermost second gate pattern 222b among the plurality of second gate patterns 220 may correspond to the vertical level of the upper surface 122b_TS of the uppermost first gate pattern 122b among the plurality of first gate patterns 120. For example, a vertical level 222a_TS of a lowermost second gate pattern 222a among the plurality of second gate patterns 220 may be lower than the vertical level 122a_TS of the lowermost first gate pattern 122a among the plurality of first gate patterns 120. In other words, the number of layers of the plurality of second gate patterns 220 may be greater than the number of layers of the plurality of first gate patterns 120. That is, a distance L1 between an upper surface of the first lower wiring line 360 in the first device region R1 and the lower surface 122a_BS of the lowermost first gate pattern 122a among the plurality of first gate patterns 120 may be greater than a distance L2 between an upper surface of a second lower wiring line 460 in the second device region R2 and a lower surface 222a_BS of the lowermost second gate pattern 222a among the plurality of second gate patterns 220.

In addition to the above description, the description of the plurality of second gate patterns 220 may correspond to, or similarly be applied to, the description of the plurality of first gate patterns 120 of the first device region R1.

A second gate insulating film 230 may be disposed between the second gate pattern 220 and the second sheet pattern NS2, between the second gate pattern 220 and the third lower insulating layer 210, between the second gate pattern 220 and the third source/drain pattern 252, and between the second gate pattern 220 and the fourth source/drain pattern 254. In addition to the above description, the description of the second gate insulating film 230 may correspond to, or similarly be applied to, the description of the first gate insulating film 130 of the first device region R1.

The description of a second gate spacer 242 may correspond to, or similarly be applied to, the description of the first gate spacer 142 of the first device region R1. In addition, the description of a second gate capping pattern 244 may correspond to, or be applied similarly to, the description of the first gate capping pattern 144 of the first device region R1.

The description of the third source/drain pattern 252 may correspond to, or similarly be applied to, the description of the first source/drain pattern 152 of the first device region R1. In addition, the description of the fourth source/drain pattern 254 may correspond to, or similarly be applied to, the description of the second source/drain pattern 154 of the first device region R1.

A thickness of the source/drain pattern included in the first device region R1 including the low layer channel pattern may correspond to a thickness of the source/drain pattern included in the second device region R2 including the high layer channel pattern. For example, the vertical level of the lower surface of each of the first and second source/drain patterns 152 and 154 may correspond to a vertical level of a lower surface of each of the third and fourth source/drain patterns 252 and 254.

The source/drain pattern included in the first device region R1 including the low layer channel pattern may be formed longer in the third direction D3 than the plurality of second gate patterns 220 of the second device region R2 including the high layer channel pattern. For example, the vertical level of the lower surface of the first source/drain pattern 152 may be lower than a vertical level of the lower surface 222a_BS of the lowermost second gate pattern 222a in the second device region R2. In addition, a vertical level of a lower surface 154_BS of the second source/drain pattern 154 may be lower than the vertical level of the lower surface 222a_BS of the lowest second gate pattern 222a of the second device region R2. In other words, a distance L3 between the lower surface 154_BS of the second source/drain pattern 154 of the first device region R1 and the upper surface of the first lower wiring line 360 may be less than the distance L2 between the lower surface 222a_BS of the lowermost second gate pattern 222a among the second device region R2 and the upper surface of the first lower wiring line 360.

This structure may be a result of the fact that the first device region R1 and the second device region R2 are formed under the same process conditions. For example, a vertical level of the lower surface 154_BS of the second source/drain pattern 154 in the first device region R1 and a vertical level of a lower surface 254_BS of the fourth source/drain pattern 254 in the second device region R2 may correspond to each other. That is, the distance L3 between the lower surface 154_BS of the second source/drain pattern 154 and the upper surface of the first lower wiring line 360 and a distance L4 between the lower surface 254_BS of the fourth source/drain pattern 254 and the upper surface of the second lower wiring line 460 may correspond to each other.

The description of the second etching stop film 260 may correspond to, or similarly be applied to, the description of the first etching stop film 160 of the first device region R1. Furthermore, the description of the second interlayer insulating film 270 may correspond to, or similarly be applied to, the description of the first etching stop film 160 of the first device region R1.

The second upper contact 412 may be connected to an upper surface of the fourth source/drain pattern 254. The second upper contact 412 may be positioned at a lower vertical level than the uppermost second sheet pattern among the plurality of second sheet patterns NS2. For example, a vertical level of a lower surface 412_BS of the second upper contact 412 may be lower than a vertical level of the upper surface 222b_TS of an uppermost second gate pattern 222b among the second lower gate patterns 222. In addition to the above description, the description of the second upper contact 412 may correspond to, or similarly be applied to, the description of the first upper contact 312 of the first device region R1.

The description of the second upper via 420 may correspond to, or similarly be applied to, the description of the first upper via 320 of the first device region R1. In addition, the description of the third upper insulating layer 442 may correspond to, or be applied similarly to, the description of the first upper insulating layer 342 of the first device region R1.

The second upper wiring structure FS2 may be disposed on the third upper insulating layer 442. The second upper wiring structure FS2 may include a second upper wiring line 430 and a fourth upper insulating layer 444. The second upper wiring structure FS2 of the second device region R2 may be the same as the first upper wiring structure FS1 of the first device region R1. For example, the second upper insulating layer 344 of the first device region R1 and the fourth upper insulating layer 444 of the second device region R2 may be identical to each other. In addition, the first upper wiring line 330 of the first device region R1 and the second upper wiring line 430 of the second device region R2 may be identical to each other. However, the disclosure is not limited thereto. The second upper wiring structure FS2 of the second device region R2 and the first upper wiring structure FS1 of the first device region R1 may be configured differently from each other.

In addition to the above description, the description of the second upper wiring structure FS2 may correspond to, or similarly be applied to, the description of the first upper wiring structure FS1 of the first device region R1.

The description of the second lower contact 450 may correspond to, or similarly be applied to, the description of the first lower contact 350 of the first device region R1. For example, a vertical level of an upper surface 450_TS of the second lower contact 450 may be higher than the vertical level of the lower surface 222a_BS of the lowermost gate pattern among the plurality of second gate patterns 220. The second lower contact 450 may overlap with the plurality of second gate patterns 220 in the first direction D1. For example, the plurality of second gate patterns 220 may include the gate patterns overlapping with the second lower contact 450 in the first direction D1.

The second lower wiring structure BS2 may be disposed on the lower surface of the third lower insulating layer 210. The second lower wiring structure BS2 may include the second lower wiring line 460 and a fourth lower insulating layer. The second lower wiring structure BS2 may be a backside power delivery network (BSPDN). The second lower wiring structure BS2 of the second device region R2 may be the same as the first lower wiring structure BS1 of the first device region R1. For example, the third lower insulating layer of the first device region R1 and the fourth lower insulating layer of the second device region R2 may be identical to each other. In addition, the first lower wiring line 360 of the first device region R1 and the second lower wiring line 460 of the second device region R2 may be identical to each other. However, the disclosure is not limited to the above. The second lower wiring structure BS2 of the second device region R2 and the first lower wiring structure BS1 of the first device region R1 may be configured differently from each other.

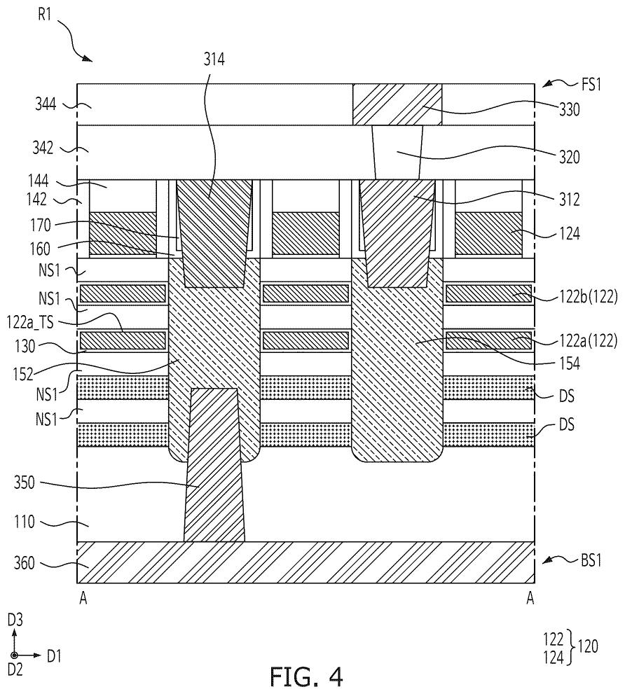

FIG. 4 is a diagram provided to explain a semiconductor device. For reference, FIG. 4 may be a diagram corresponding to a cross-sectional view taken along line A-A of FIG. 1. The semiconductor device of FIG. 4 may be substantially the same as the semiconductor device described with reference to FIGS. 1 to 3, except that it further includes a dummy sheet pattern DS. For convenience of description, differences from the configurations described above in FIGS. 1 to 3 will be primarily described.

The first device region R1 may further include at least one dummy sheet pattern DS disposed below the plurality of first gate patterns 120 and alternately stacked with the plurality of first sheet patterns NS1. The dummy sheet pattern DS may be stacked on the first lower insulating layer 110 in a vertical direction (e.g., the third direction D3). The plurality of first gate patterns 120 may be disposed on the dummy sheet pattern DS. The dummy sheet pattern DS may be a nanowire pattern.

The dummy sheet pattern DS may include a semiconductor material, for example, a group IV semiconductor material, a group III-V semiconductor material, a group II-VI semiconductor material, or any combination of these. The group III-V semiconductor material may include, for example, silicon (Si), germanium (Ge), or any combination of these. The group IV semiconductor material may include, for example, gallium arsenide (GaAs), indium phosphorus (InP), gallium phosphorus (GaP), indium arsenide (InAs), indium antimony (InSb), indium arsenide (InGaAs), or any combination of these. The group II-VI semiconductor material may include, for example, zinc telluride (ZnTe), cadmium sulfide (CdS), or any combination of these.

In another aspect, the dummy sheet pattern DS may include at least one of silicon oxide, silicon nitride, silicon oxynitride, or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or any combination of these. However, the disclosure is not limited to the above.

A vertical level of each layer included in the stacked structure of the first gate pattern 120 and the dummy sheet pattern DS of the first device region R1 may correspond to a vertical level of each layer included in the stacked structure of the second gate pattern 220 of the second device region R2. For example, the vertical level of each of the plurality of first gate patterns 120 may correspond to the vertical level of each gate pattern of some of the plurality of second gate patterns 220. In addition, the vertical level of each of the at least one dummy sheet pattern DS may correspond to the vertical level of each of the remaining gate patterns of the plurality of second gate patterns 220. This structure may be due to the fact that the first device region R1 and the second device region R2 are formed under the same process conditions.

The first lower contact 350 may overlap with the dummy sheet pattern DS in the first direction D1. A vertical level of the upper surface of the first lower contact 350 may be higher than a vertical level of the lower surface of the lowermost dummy sheet pattern DS.

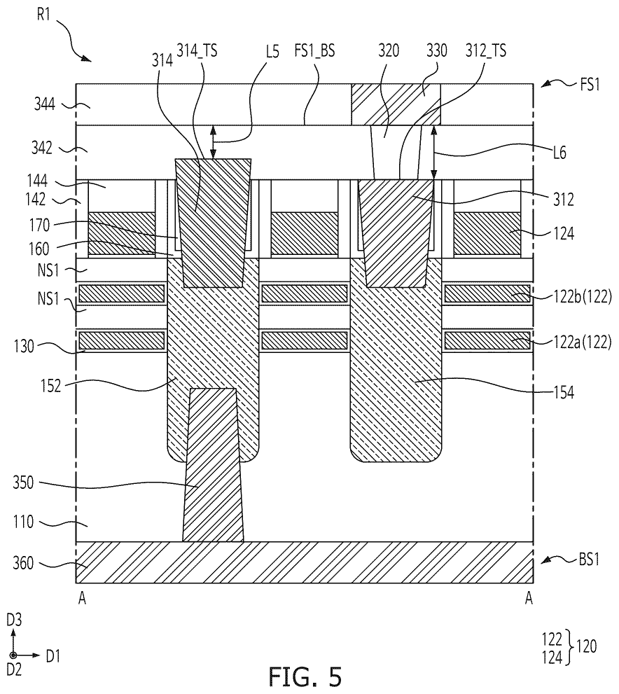

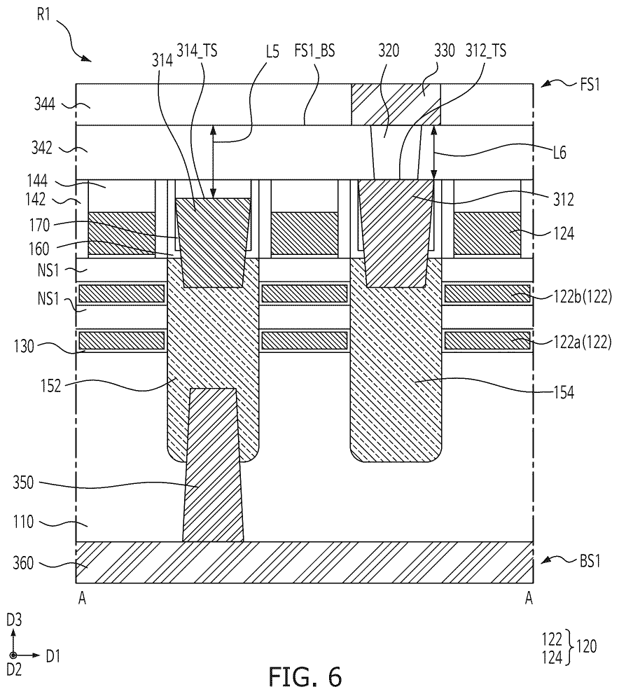

FIGS. 5 and 6 are diagrams provided to explain a semiconductor device. For reference, each of FIGS. 5 and 6 may be a cross-sectional view taken along line A-A of FIG. 1. The semiconductor device of FIGS. 5 and 6 may be substantially the same as the semiconductor device described with reference to FIGS. 1 to 4 except for the shape of the upper dummy contact 314. For convenience of description, differences from the configurations described above in FIGS. 1 to 4 will be primarily described.

A thickness of the upper dummy contact 314 may be different from a thickness of the first upper contact 312. A vertical level of a lower surface of the upper dummy contact 314 and a vertical level of a lower surface of the first upper contact 312 may correspond to each other. In this case, a vertical level of an upper surface of the upper dummy contact 314 and a vertical level of an upper surface of the first upper contact 312 may be different from each other.

For example, referring to FIG. 5, a distance L5 between an upper surface 314_TS of the upper dummy contact 314 and a lower surface FS1_BS of the first upper wiring structure FS1 may be less than a distance L6 between an upper surface 312_TS of the first upper contact 312 and the lower surface FS1_BS of the first upper wiring structure FS1. In this case, the upper surface 314_TS of the upper dummy contact 314 may be disposed in the first upper insulating layer 342.

In another example, referring to FIG. 6, the distance L5 between the upper surface 314_TS of the upper dummy contact 314 and the lower surface FS1_BS of the first upper wiring structure FS1 may be greater than the distance L6 between the upper surface 312_TS of the first upper contact 312 and the lower surface FS1_BS of the first upper wiring structure FS1. In this case, the upper surface 314_TS of the upper dummy contact 314 may be disposed in the first interlayer insulating film 170.

A vertical level of the lower surface FS1_BS of the first upper wiring structure FS1 may correspond to a vertical level of the lower surface of the first upper wiring line 330.

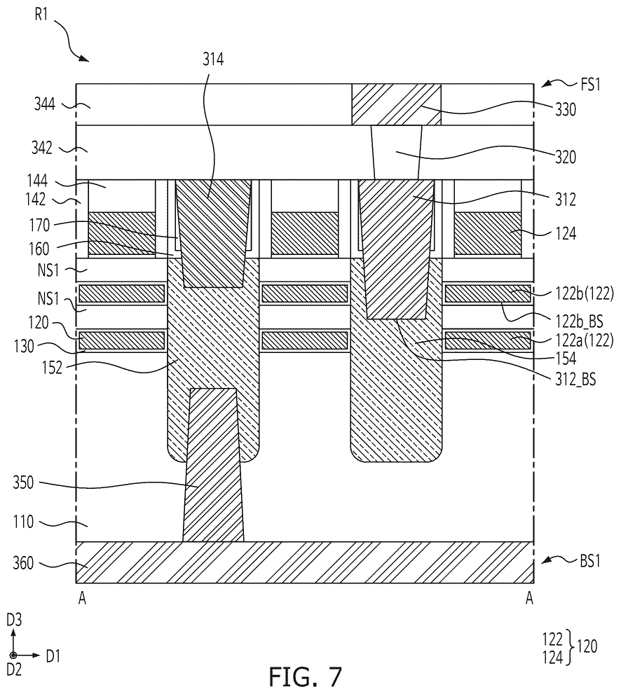

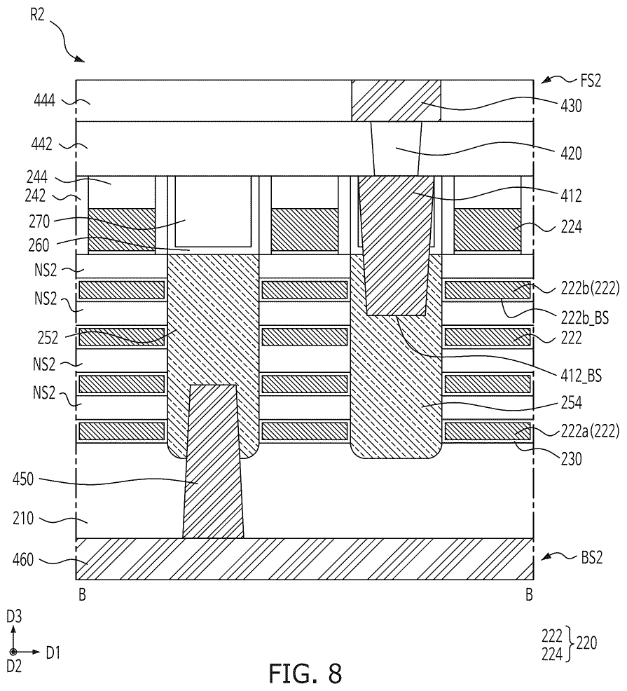

FIGS. 7 and 8 are diagrams provided to explain a semiconductor device. For reference, FIG. 7 may be a diagram corresponding to a cross-sectional view taken along line A-A of FIG. 1. In addition, FIG. 8 may be a diagram corresponding to a cross-sectional view taken along line B-B of FIG. 1. The semiconductor device of FIG. 7 may be substantially the same as the semiconductor device described with reference to FIGS. 1 to 6, except for the shape of the first upper contact 312. In addition, the semiconductor device of FIG. 8 may be substantially the same as the semiconductor device described with reference to FIGS. 1 to 6, except for the shape of the second upper contact 412. For convenience of description, differences from the configurations described above in FIGS. 1 to 6 will be primarily described.

The first upper contact 312 of the first device region R1 may be positioned at a lower vertical level than the uppermost first gate pattern 122b among the first lower gate patterns 122. For example, referring to FIG. 7, a vertical level of the lower surface 312_BS of the first upper contact 312 may be lower than a vertical level of a lower surface 122b_BS of the uppermost first gate pattern 122b among the first lower gate patterns 122.

The second upper contact 412 of the second device region R2 may be positioned at a lower vertical level than the uppermost second gate pattern 222b among the second lower gate patterns 222. For example, referring to FIG. 8, a vertical level of the lower surface 412_BS of the second upper contact 412 may be lower than the vertical level of the lower surface 222b_BS of the uppermost second gate pattern 222b among the second lower gate patterns 222.

The shape of the first upper contact 312 of the first device region R1 and the shape of the second upper contact 412 of the second device region R2 may correspond to each other. For example, the thickness of the first upper contact 312 and the second upper contact 412 may correspond to each other. That is, a vertical level of the upper surface of the first upper contact 312 and a vertical level of the upper surface of the second upper contact 412 may correspond to each other. In addition, the vertical level of the lower surface 312_BS of the first upper contact 312 and the vertical level of the lower surface 412_BS of the second upper contact 412 may correspond to each other. However, the disclosure is not limited thereto. The shape of the first upper contact 312 of the first device region R1 and the shape of the second upper contact 412 of the second device region R2 may be different from each other.

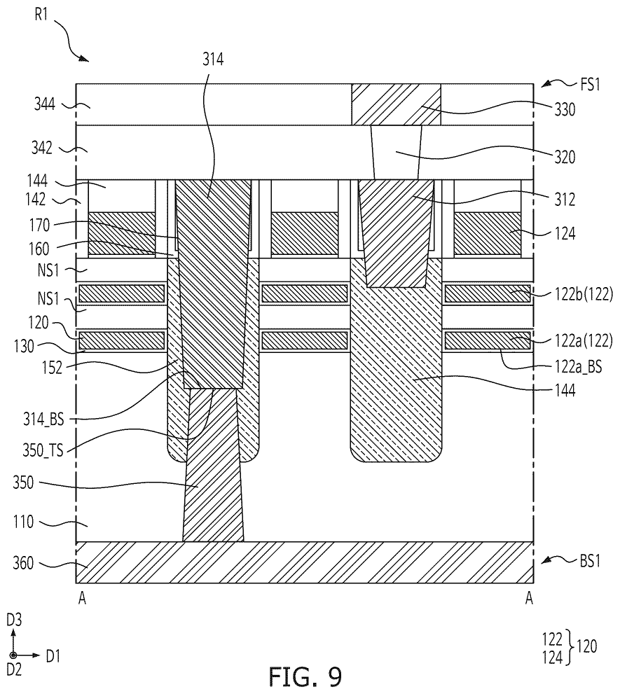

FIG. 9 is a diagram provided to explain a semiconductor device. For reference, FIG. 9 may be a diagram corresponding to a cross-sectional view taken along line A-A of FIG. 1. The semiconductor device of FIG. 9 may be substantially the same as the semiconductor device described with reference to FIGS. 1 to 8, except for the shape of the upper dummy contact 314. For convenience of description, differences from the configurations described above in FIGS. 1 to 8 will be primarily described.

The upper dummy contact 314 may be positioned at a lower vertical level than the lowermost first gate pattern 122a among the plurality of first gate patterns 120. For example, a vertical level of a lower surface 314_BS of the upper dummy contact 314 may be lower than a vertical level of the lower surface 122a_BS of the lowermost first gate pattern 122a among the plurality of first gate patterns 120. The upper dummy contact 314 may overlap with the plurality of first gate patterns 120 in the first direction D1. For example, all of the gate patterns included in the plurality of first gate patterns 120 may overlap with the upper dummy contact 314 in the first direction D1.

The upper dummy contact 314 may be connected to the first lower contact 350. For example, the lower surface 314_BS of the upper dummy contact 314 may be in contact with the upper surface 350_TS of the first lower contact 350. An interface between the upper dummy contact 314 and the first lower contact 350 may not exist. In this case, the upper dummy contact 314 and the first lower contact 350 may appear to be formed as a single body.

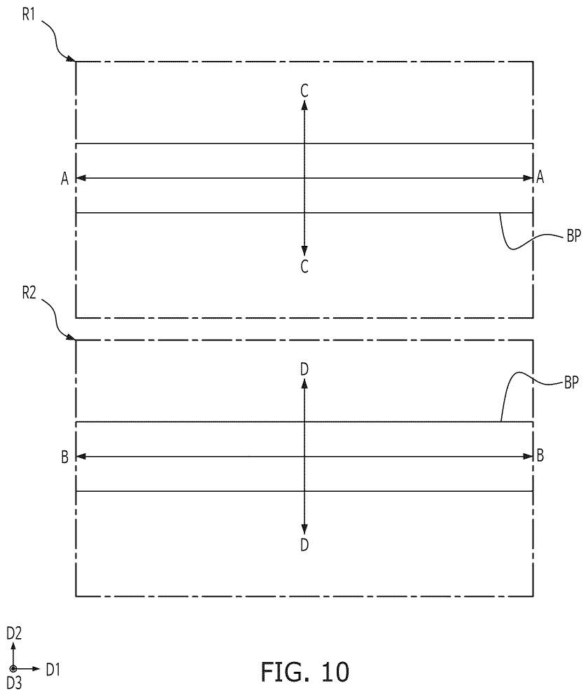

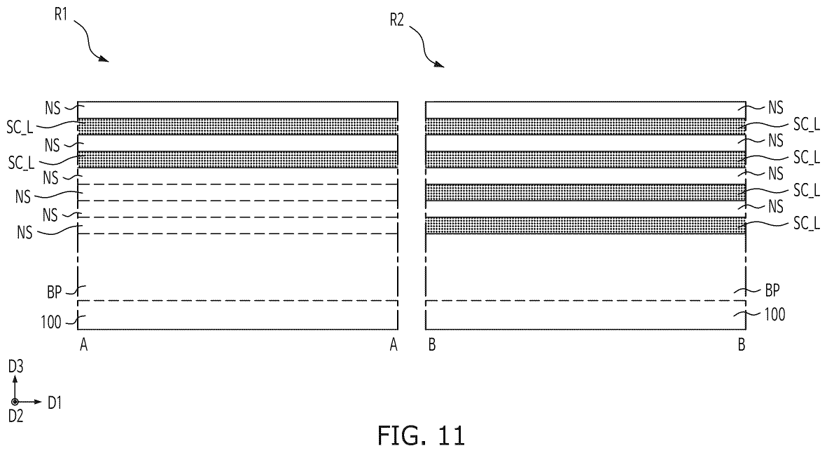

FIGS. 10 to 16 are diagrams showing intermediate stages, which are provided to explain a method for manufacturing a semiconductor device according to some aspects. For reference, FIG. 10 is a plan view provided to explain a method for manufacturing a semiconductor device, and FIGS. 11 to 16 include cross-sectional views taken along line A-A and cross-sectional views taken along line B-B of FIG. 10.

Referring to FIGS. 10 and 11, a stacked structure of a plurality of sheet patterns NS and a plurality of sacrificial semiconductor layers SC_L may be formed in the first device region R1 and the second device region R2. The first device region R1 and the second device region R2 in FIGS. 10 to 16 represent respective corresponding regions of a worksheet in the manufacturing process for forming the first device region R1 and the second device region R2 of the semiconductor device described with reference to FIGS. 1 to 9.

Specifically, in the first device region R1, a lower pattern BP may be formed on a substrate 100, the sheet patterns NS may be repeatedly stacked, and the plurality of sacrificial semiconductor layers SC_L and the plurality of sheet patterns NS may be alternately stacked.

In addition, in the second device region R2, the lower pattern BP may be formed on the substrate 100, and the plurality of sacrificial semiconductor layers SC_L and the plurality of sheet patterns NS, which are alternately stacked on the lower pattern BP, may be formed.

The substrate 100 may be a bulk silicon or a silicon-on-insulator (SOI). On the other hand, the substrate 100 may include silicon germanium (SiGe), silicon germanium on insulator (SGOI), indium antimony, lead tellurium compound, indium arsenide, indium phosphide, gallium arsenic, or gallium antimony, but is not limited thereto.

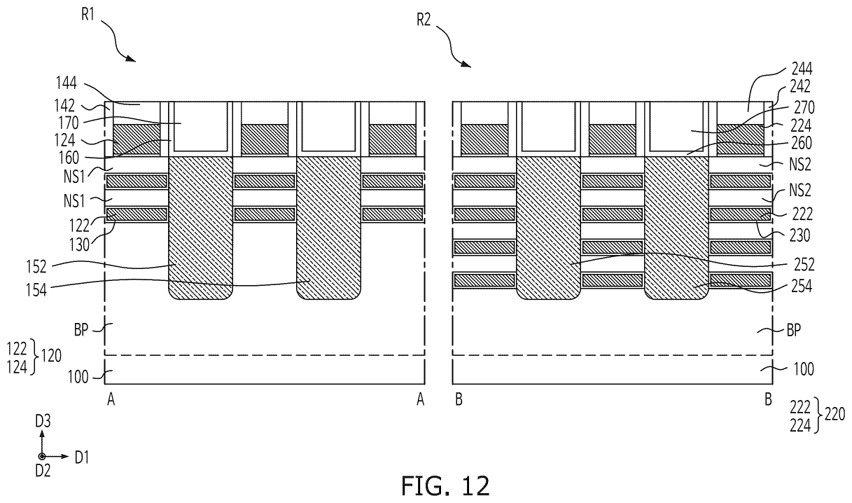

Referring to FIG. 12, in the first device region R1, the first source/drain pattern 152 and the second source/drain pattern 154 may be formed on the lower pattern BP. The first source/drain pattern 152 and the second source/drain pattern 154 may be epitaxial patterns formed by a selective epitaxial growth process. The first gate pattern 120 may be formed by a replacement process, and the first gate spacer 142, the first gate capping pattern 144, the first etching stop film 160, and the first interlayer insulating film 170 may be formed. Specifically, the sacrificial semiconductor layer SC_L may be removed and the plurality of sheet patterns NS may be exposed. In the first device region R1 of the substrate 100, the first gate insulating film 130 and the first gate pattern 120 may be sequentially formed on the plurality of sheet patterns NS. The first gate capping pattern 144 may be formed and the first etching stop film 160 and the first interlayer insulating film 170 may be formed.

In addition, in the second device region R2, the third source/drain pattern 252 and the fourth source/drain pattern 254 may be formed on the lower pattern BP. The third source/drain pattern 252 and the fourth source/drain pattern 254 may be epitaxial patterns formed by a selective epitaxial growth process. The second gate pattern 220 may be formed by a replacement process and the second gate spacer 242, the second gate capping pattern 244, the second etching stop film 260, and the second interlayer insulating film 270 may be formed. Specifically, the sacrificial semiconductor layer SC_L may be removed and the plurality of sheet patterns NS may be exposed. In the second device region R2 of the substrate 100, the second gate insulating film 230 and the second gate pattern 220 may be sequentially formed on the plurality of sheet patterns NS. The second gate capping pattern 244 may be formed and the second etching stop film 260 and the second interlayer insulating film 270 may be formed.

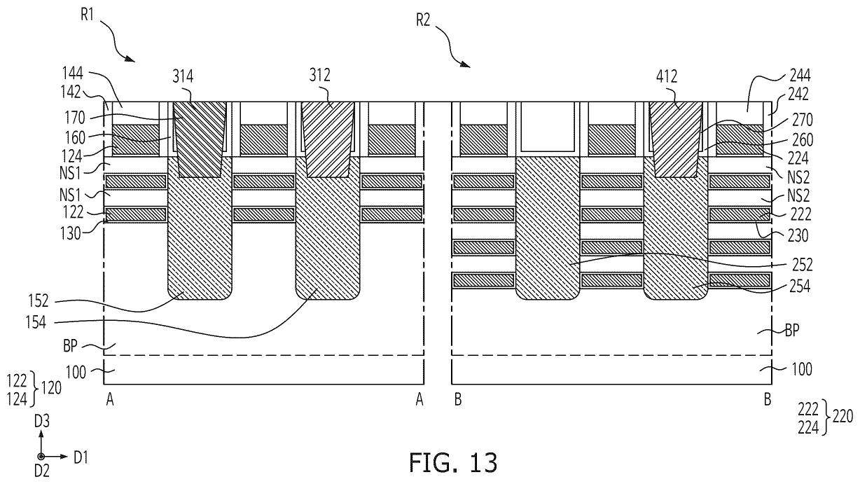

Referring to FIG. 13, in the first device region R1, the upper dummy contact 314 may be formed on the first source/drain pattern 152, and the first upper contact 312 may be formed on a second source/drain pattern 154. In addition, in the second device region R2, the second upper contact 412 may be formed on the fourth source/drain pattern 254.

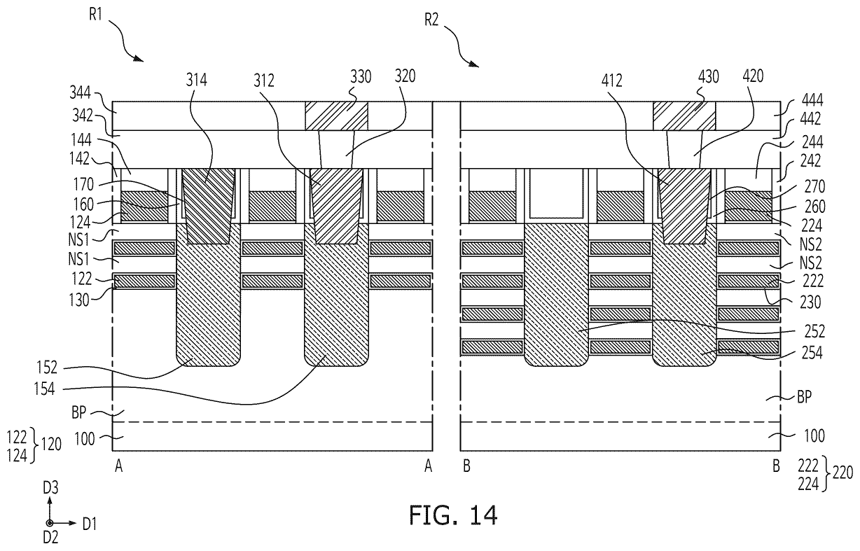

Referring to FIG. 14, in the first device region R1, the first upper insulating layer 342 may be formed on the first gate capping pattern 144 and the first interlayer insulating film 170, and the first upper via 320 may be formed on the first upper contact 312. The second upper insulating layer 344 may be formed on the first upper insulating layer 342, and the first upper wiring line 330 may be formed on the first upper via 320.

In addition, in the second device region R2, the third upper insulating layer 442 may be formed on the second gate capping pattern 244 and the second interlayer insulating film 270, and the second upper via 420 may be formed on the second upper contact 412. The fourth upper insulating layer 444 may be formed on the third upper insulating layer 442, and the second upper wiring line 430 may be formed on the second upper via 420.

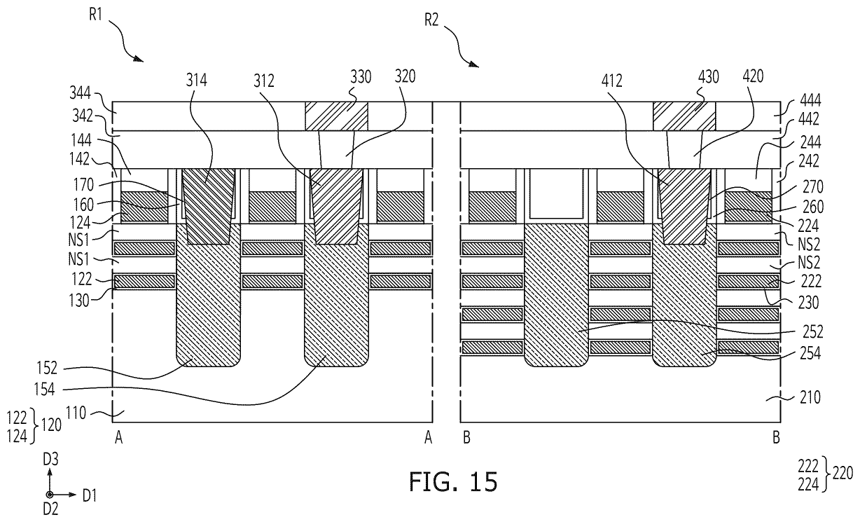

Referring to FIG. 15, the substrate 100 and the lower pattern BP may be removed from the first device region R1 and the first lower insulating layer 110 may be formed. The first lower insulating layer 110 may be disposed below each of the first gate pattern 120 and the first and second source/drain patterns 152 and 154.

In addition, the substrate 100 and the lower pattern BP may be removed from the second device region R2 and the third lower insulating layer 210 may be formed. The third lower insulating layer 210 may be disposed below each of the second gate pattern 220 and the third and fourth source/drain patterns 252 and 254.

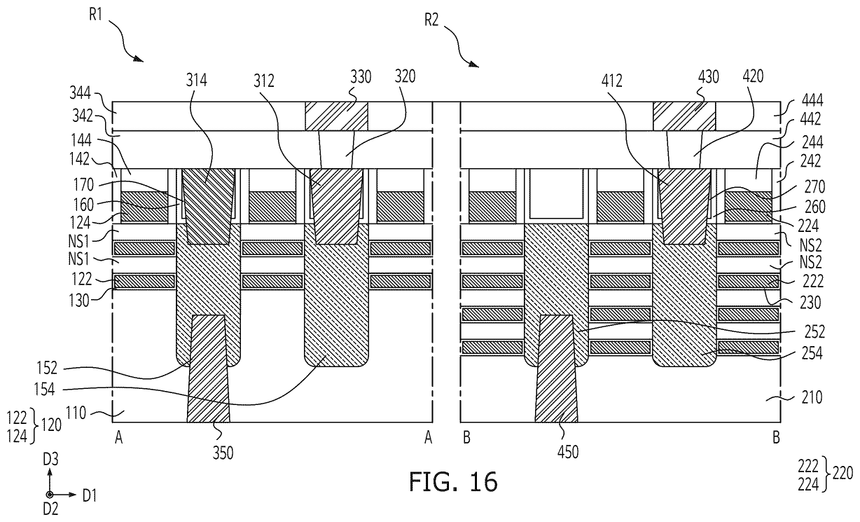

Referring to FIG. 16, in the first device region R1, the first lower contact 350 may be formed in the first lower insulating layer 110. The first lower contact 350 may be formed connected to a lower portion of the first source/drain pattern 152. The first lower wiring structure (e.g., BS1 in FIG. 2) including the first lower wiring line (e.g., 360 in FIG. 2) may be formed below the first lower contact 350 and the first lower insulating layer 110 to manufacture the semiconductor device of FIG. 2.

In addition, in the second device region R2, the second lower contact 450 may be formed in the third lower insulating layer 210. The second lower contact 450 may be formed connected to a lower portion of the third source/drain pattern 252. The second lower wiring structure (e.g., BS2 in FIG. 3) including the second lower wiring line (e.g., 460 in FIG. 3) may be formed below the second lower contact 450 and the third lower insulating layer 210 to manufacture the semiconductor device of FIG. 3.

The semiconductor devices of FIGS. 5 to 9 may be manufactured using a method similar to the manufacturing method described above.

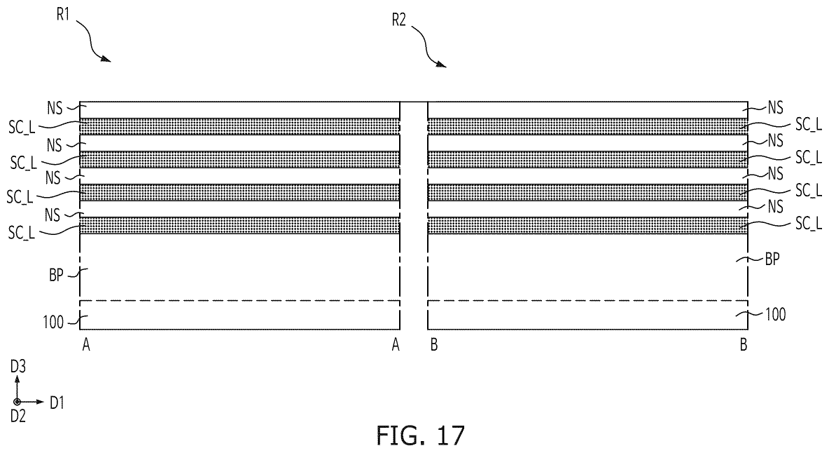

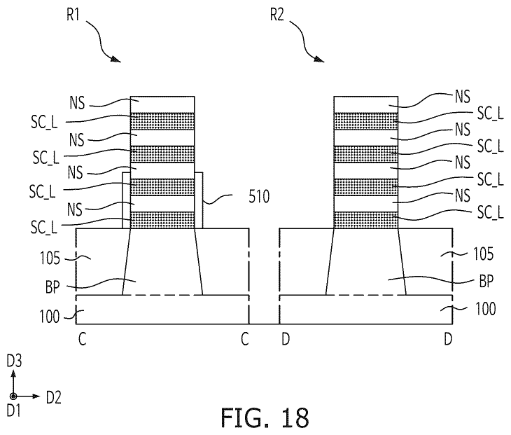

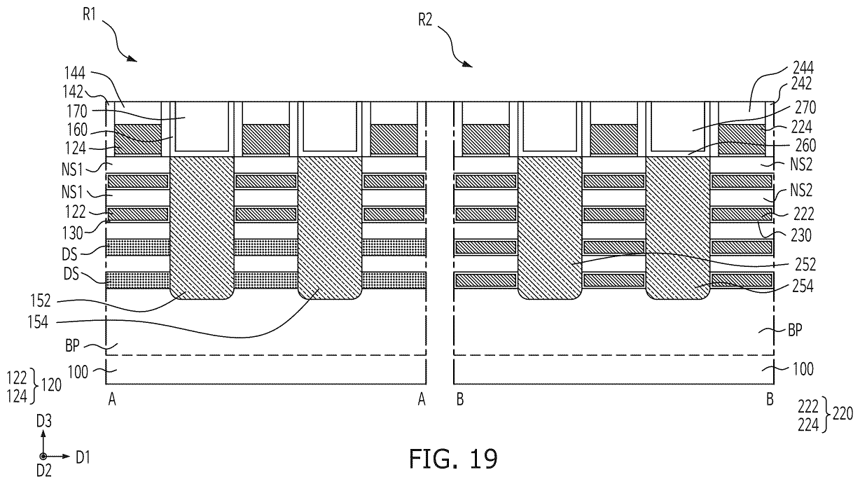

FIGS. 17 to 19 are diagrams showing intermediate stages, which are provided to explain a method for manufacturing a semiconductor device according to some aspects. For reference, FIGS. 17 and 19 include a cross-sectional view taken along line A-A and a cross-sectional view taken along line B-B of FIG. 10, and FIG. 18 includes a cross-sectional view taken along line C-C and a cross-sectional view taken along line D-D of FIG. 10.

Referring to FIG. 17, a stacked structure of the plurality of sheet patterns NS and the plurality of sacrificial semiconductor layers SC_L may be formed in the first device region R1 and the second device region R2. The first device region R1 and the second device region R2 in FIGS. 17 to 19 represent respective corresponding regions of a worksheet in the manufacturing process for forming the first device region R1 and the second device region R2 of the semiconductor device described with reference to FIGS. 1 to 9.

Specifically, in the first device region R1 and the second device region R2, or in the second device region R2, the lower pattern BP, and the plurality of sacrificial semiconductor layers SC_L and the plurality of sheet patterns NS, which are alternately stacked on the lower pattern BP, may be formed on the substrate 100.

Referring to FIG. 18, in the first device region R1, a liner 510 may be formed on side surfaces of a lower region of the stacked structure of the plurality of sheet patterns NS and the plurality of sacrificial semiconductor layers SC_L in the second direction D2. The liner 510 may be disposed on a field insulating film 105, but the scope of the disclosure is not limited thereto. The liner 510 may serve to prevent the sacrificial semiconductor layer disposed in the lower region of the stacked structure from being removed during the replacement process for controlling the sacrificial semiconductor layer SC_L.

Referring to FIG. 19, in the first device region R1, the first source/drain pattern 152 and the second source/drain pattern 154 may be formed on the lower pattern BP, and the first gate pattern 120 may be formed by a replacement process. In this case, among the plurality of sacrificial semiconductor layers SC_L, the sacrificial semiconductor layer SC_L in the lower region may not be removed by the liner 510 and remain as the dummy sheet pattern DS. The first gate spacer 142, the first gate capping pattern 144, the first etching stop film 160, and the first interlayer insulating film 170 may be formed.

The liner 510 may not be formed. In this case, the sacrificial semiconductor layer SC_L in the lower region of the plurality of sacrificial semiconductor layers SC_L may be replaced with an insulating material to form the dummy sheet pattern DS.

In addition, in the second device region R2, the third source/drain pattern 252 and the fourth source/drain pattern 254 may be formed on the lower pattern BP. The second gate pattern 220 may be formed by a replacement process and the second gate spacer 242, the second gate capping pattern 244, the second etching stop film 260, and the second interlayer insulating film 270 may be formed.

The manufacturing method described with reference to FIGS. 13 to 16 may be performed to manufacture the semiconductor device of FIG. 4.

The manufacturing method described with reference to FIGS. 10 to 19 may be performed under the same process conditions in the first device region R1 and the second device region R2. Accordingly, components with shapes and sizes corresponding to the components included in the first device region R1 and the second device region R2 may be included. However, the disclosure is not limited to the above.

Although the present disclosure has been described above by way of certain aspects and drawings, the present disclosure is not limited thereto, and various changes and modifications can be made within the equivalent scope of the technical idea of the present disclosure and the claims to be described below by those of ordinary skill in the art.

What is claimed is:

1. A semiconductor device comprising:
a first device region comprising:
a plurality of first sheet patterns stacked in a vertical direction;
a plurality of first gate patterns alternately stacked with the plurality of first sheet patterns;
a first source/drain pattern on one side of the plurality of first sheet patterns;
a second source/drain pattern on another side of the plurality of first sheet patterns;
an upper dummy contact connected to an upper surface of the first source/drain pattern; and
a first upper wiring structure spaced apart from the upper dummy contact in the vertical direction; and
a second device region comprising:
a plurality of second sheet patterns stacked in the vertical direction;
a plurality of second gate patterns alternately stacked with the plurality of second sheet patterns;
a third source/drain pattern on one side of the plurality of second sheet patterns; and
a fourth source/drain pattern on the other side of the plurality of second sheet patterns,
wherein a number of layers of the plurality of first gate patterns is less than a number of layers of the plurality of second gate patterns,
wherein a vertical level of a lowermost first gate pattern among the plurality of first gate patterns is higher than a vertical level of a lowermost second gate pattern among the plurality of second gate patterns, and
wherein the upper dummy contact is insulated from a wiring line included in the first upper wiring structure.

2. The semiconductor device of claim 1, wherein a vertical level of a lower surface of the second source/drain pattern is lower than a vertical level of a lower surface of the lowermost second gate pattern.

3. The semiconductor device of claim 1, wherein a vertical level of a lower surface of the second source/drain pattern corresponds to a vertical level of a lower surface of the fourth source/drain pattern.

4. The semiconductor device of claim 1, wherein the first device region further comprises one or more dummy sheet patterns below the plurality of first gate patterns, and
wherein the one or more dummy sheet patterns are alternately stacked with the plurality of first sheet patterns.

5. The semiconductor device of claim 4, wherein a vertical level of each of the plurality of first gate patterns corresponds to a vertical level of a respective gate pattern of the plurality of second gate patterns, and
wherein a vertical level of each of the one or more dummy sheet patterns corresponds to a vertical level of a respective gate pattern of the plurality of second gate patterns.

6. The semiconductor device of claim 1, wherein the first device region further comprises a first upper contact connected to an upper surface of the second source/drain pattern,
wherein the first upper wiring structure comprises a first upper wiring line, and
wherein the first upper contact is connected to the first upper wiring line.

7. The semiconductor device of claim 6, wherein the plurality of first gate patterns comprises:
lower gate patterns between the plurality of first sheet patterns; and
an upper gate pattern on the plurality of first sheet patterns, and
wherein a vertical level of a lower surface of the first upper contact is lower than a vertical level of an upper surface of an uppermost first gate pattern among the lower gate patterns.

8. The semiconductor device of claim 6, wherein the plurality of first gate patterns comprises:
lower gate patterns between the plurality of first sheet patterns; and
an upper gate pattern on the plurality of first sheet patterns, and
wherein a vertical level of a lower surface of the first upper contact is lower than a vertical level of a lower surface of an uppermost first gate pattern among the lower gate patterns.

9. The semiconductor device of claim 6, wherein a distance between an upper surface of the upper dummy contact and a lower surface of the first upper wiring structure is less than a distance between an upper surface of the first upper contact and the lower surface of the first upper wiring structure.

10. The semiconductor device of claim 6, wherein a distance between an upper surface of the upper dummy contact and a lower surface of the first upper wiring structure is greater than a distance between an upper surface of the first upper contact and the lower surface of the first upper wiring structure.

11. The semiconductor device of claim 6, wherein the second device region further comprises:
a second upper contact connected to an upper surface of the fourth source/drain pattern; and
a second upper wiring structure comprising a second upper wiring line connected to the second upper contact, and
wherein a vertical level of a lower surface of the second upper contact corresponds to a vertical level of a lower surface of the first upper contact.

12. The semiconductor device of claim 1, wherein the first device region further comprises:
a first lower contact connected to a lower surface of the first source/drain pattern; and
a first lower wiring line connected to the first lower contact.

13. The semiconductor device of claim 12, wherein a vertical level of an upper surface of the first lower contact is lower than a vertical level of a lower surface of the lowermost first gate pattern.

14. The semiconductor device of claim 12, wherein a lower surface of the upper dummy contact is lower than a vertical level of a lower surface of the lowermost first gate pattern.

15. The semiconductor device of claim 12, wherein the upper dummy contact is connected to the first lower contact.

16. The semiconductor device of claim 12, wherein the second device region further comprises:
a second lower contact connected to a lower surface of the third source/drain pattern; and
a second lower wiring line connected to the second lower contact, and
wherein a vertical level of an upper surface of the second lower contact corresponds to a vertical level of an upper surface of the first lower contact.

17. A semiconductor device comprising:
a first device region comprising:
a plurality of first sheet patterns stacked in a vertical direction;
a plurality of first gate patterns alternately stacked with the plurality of first sheet patterns;
a first source/drain pattern on one side of the plurality of first sheet patterns;
a second source/drain pattern on the other side of the plurality of first sheet patterns, an upper dummy contact connected to an upper surface of the first source/drain pattern;
a first lower contact connected to a lower surface of the first source/drain pattern;
a first lower wiring line connected to the first lower contact;
a first upper contact connected to an upper surface of the second source/drain pattern; and
a first upper wiring structure connected to the first upper contact, the first upper wiring structure comprising a first upper wiring line; and
a second device region comprising:
a plurality of second sheet patterns stacked in the vertical direction;
a plurality of second gate patterns alternately stacked with the plurality of second sheet patterns;
a third source/drain pattern on one side of the plurality of second sheet patterns;
a fourth source/drain pattern on another side of the plurality of second sheet patterns;
a second lower contact connected to a lower surface of the third source/drain pattern; and
a second lower wiring line connected to the second lower contact,
wherein a number of layers of the plurality of first gate patterns is less than a number of layers of the plurality of second gate patterns,
wherein a distance between an upper surface of the first lower wiring line and a lower surface of a lowermost first gate pattern among the plurality of first gate patterns is greater than a distance between an upper surface of the second lower wiring line and a lower surface of a lowermost second gate pattern among the plurality of second gate patterns, and
wherein the upper dummy contact is insulated from a wiring line included in the first upper wiring structure.

18. The semiconductor device of claim 17, wherein a distance between the upper surface of the first lower wiring line and a lower surface of the second source/drain pattern is less than a distance between the upper surface of the second lower wiring line and a lower surface of the lowermost second gate pattern.

19. The semiconductor device of claim 17, further comprising:
a first lower wiring structure including the first lower wiring line; and
a second lower wiring structure including the second lower wiring line,
wherein the first and the second lower wiring structures comprise a backside power delivery network.

20. A semiconductor device comprising:
a first device region comprising:
a plurality of first sheet patterns stacked in a vertical direction;
a plurality of first gate patterns alternately stacked with the plurality of first sheet patterns;
a first source/drain pattern on one side of the plurality of first sheet patterns;
a second source/drain pattern disposed on another side of the plurality of first sheet patterns;
an upper dummy contact connected to an upper surface of the first source/drain pattern;
a first lower contact connected to a lower surface of the first source/drain pattern;
a first lower wiring line connected to the first lower contact;
a first upper contact connected to an upper surface of the second source/drain pattern; and
a first upper wiring structure connected to the first upper contact, the first upper wiring structure comprising a first upper wiring line; and
a second device region comprising:
a plurality of second sheet patterns stacked in the vertical direction;
a plurality of second gate patterns alternately stacked with the plurality of second sheet patterns;
a third source/drain pattern on one side of the plurality of second sheet patterns;
a fourth source/drain pattern on another side of the plurality of second sheet patterns;
a second lower contact connected to a lower surface of the third source/drain pattern;
a second lower wiring line connected to the second lower contact;
a second upper contact connected to an upper surface of the fourth source/drain pattern; and
a second upper wiring structure including a second upper wiring line connected to the second upper contact,
wherein a number of layers of the plurality of first gate patterns is less than a number of layers of the plurality of second gate patterns,
wherein a distance between an upper surface of the first lower wiring line and a lower surface of a lowermost first gate pattern among the plurality of first gate patterns is greater than a distance between an upper surface of the second lower wiring line and a lower surface of a lowermost second gate pattern among the plurality of second gate patterns, and
wherein the upper dummy contact is insulated from a wiring line included in the first upper wiring structure.
